(19) United States
(12) Patent Application Publication
(10) Pub. No.: US 2025/0028875 A1
(43) Pub. Date: Jan. 23, 2025

(54) COMPARATIVE FEEDBACK METRIC FOR DRIVER TRAINING

(71) Applicant: TOYOTA RESEARCH INSTITUTE, INC., Los Altos, CA (US)

(72) Inventors: Shawn MANUEL, Mountain View, CA (US); John K. SUBOSITS, Mountain View, CA (US); Yun Jung LEE, Mountain View, CA (US); Avinash BALACHANDRAN, Sunnyvale, CA (US)

(73) Assignees: TOYOTA RESEARCH INSTITUTE, INC., Los Altos, CA (US); TOYOTA JIDOSHA KABUSHIKI KAISHA, Toyota-shi (JP)

(21) Appl. No.: 18/355,772

(22) Filed: Jul. 20, 2023

(51) Int. Cl. G06F 30/20

(52) U.S. Cl. CPC G06F 30/20

(57) ABSTRACT

Systems and methods are provided for optimizing a driver's trajectory around a race track. The system can receive driver data representing driver inputs to a vehicle. A vehicle state can be determined for at least one location on the race track based on the received driver data. Expert driver data can be determined representing inputs of an expert driver at the determined vehicle state for the at least one location. The system can predict how the expert driver would proceed from each current vehicle state based on the expert driver data and map the current vehicle state at the at least one location to a recommended trajectory from each current vehicle state based on predicting how the expert driver would proceed.

### TECHNICAL FIELD

The present disclosure relates generally to race-track driving, and in particular, some implementations may relate to strategizing for races around a race track.

### DESCRIPTION OF RELATED ART

Motor-sports racing showcases the pinnacle of automotive manufacturing and driving skills, and optimizing for the race has long been one of the largest challenges in motorsports. Racing teams record a large amount of data about the vehicles and drivers to determine strategy for a particular race. In particular, this data can be used to generate simulations of a race to provide a visual aid for strategizing. These simulations can apply machine learning models that can focus on vehicle parameterization or race line optimization to generate recommendations for a vehicle and/or driver.

### BRIEF SUMMARY OF THE DISCLOSURE

According to various embodiments of the disclosed technology, a method for optimizing a driver's trajectory around a race track can comprise receiving driver data representing driver inputs to a vehicle; determining a vehicle state for at least one location on the race track based on the received driver data; determining expert driver data representing inputs of an expert driver at the determined vehicle state for the at least one location; predicting how the expert driver would proceed from each current vehicle state based on the expert driver data; and mapping the current vehicle state at the at least one location to a recommended trajectory from each current vehicle state based on predicting how the expert driver would proceed.

In some embodiments, the method further comprises displaying the recommended trajectory on a user interface as the driver simulates driving around the race track.

In some embodiments, the method further comprises updating the displayed recommended trajectory when the driver changes vehicle state.

In some embodiments, updating the displayed recommended trajectory comprises determining how the expert driver would proceed from the changed vehicle state and mapping a new recommended trajectory.

In some embodiments, the method further comprises segmenting the race track and categorizing each segment of the race track.

In some embodiments, the method further comprises categorizing the driver data based on a corresponding segment.

In some embodiments, determining how the expert driver would proceed from each current vehicle state is based on minimizing a lap time around the race track.

In some embodiments, the method further comprises training a machine learning model with reinforced learning and regulating the machine learning model with additional simulation data to match human actions.

According to various embodiments of the disclosed technology, a system for simulating driving around a race track can comprise a processor and a memory coupled to the processor to store instructions, which when executed by the processor, cause the processor to: receive driver data representing driver inputs to a vehicle; determine a current vehicle state for at least one location on the race track based on the received driver data; determine expert driver data representing inputs of an expert driver at the determined vehicle state for the at least one location; predict how the expert driver would proceed from each current vehicle state based on the expert driver data; and map the current vehicle state at the at least one location to one or more recommended vehicle settings for a remaining portion of the race track based on predicting how the expert driver would proceed.

In some embodiments, the instructions further cause the processor to display the one or more recommended vehicle settings on a user interface as the driver simulates driving around the race track.

In some embodiments, the instructions further cause the processor to segment the race track and categorize each segment of the race track.

In some embodiments, determining how the expert driver would proceed is based on a corresponding category of segment of the race track.

In some embodiments, determining how the expert driver would proceed from each current vehicle state is based on minimizing a lap time around the race track.

In some embodiments, the instructions further cause the processor to train a machine learning model with reinforced learning and regulate the machine learning model with additional simulation data to match human actions.

According to various embodiments of the disclosed technology, a non-transitory machine-readable medium can have instructions stored therein, which when executed by a processor, cause the processor to: receive driver data representing driver inputs to a vehicle; determine a current vehicle state for at least one location on a race track based on the received driver data; determine expert driver data representing inputs of an expert driver at the determined vehicle state for the at least one location; predict how the expert driver would proceed from each current vehicle state based on the expert driver data; map the current vehicle state at the at least one location to a recommended trajectory from each current vehicle state based on predicting how the expert driver would proceed; and display the recommended trajectory on a user interface as the driver traverses the race track.

In some embodiments, the instructions further cause the processor to update the displayed recommended trajectory when the driver changes vehicle state.

In some embodiments, the instructions further cause the processor to determine how the expert driver would proceed from the changed vehicle state and mapping a new recommended trajectory.

In some embodiments, the instructions further cause the processor to segment the race track and categorize each segment of the race track.

In some embodiments, the instructions further cause the processor to categorize the data based on a corresponding segment.

In some embodiments, determining how the expert driver would proceed from each current vehicle state is based on minimizing a lap time around the race track.

Other features and aspects of the disclosed technology will become apparent from the following detailed description, taken in conjunction with the accompanying drawings, which illustrate, by way of example, the features in accordance with embodiments of the disclosed technology. The summary is not intended to limit the scope of any inventions described herein, which are defined solely by the claims attached hereto.

### BRIEF DESCRIPTION OF THE DRAWINGS

The present disclosure, in accordance with one or more various embodiments, is described in detail with reference to the following figures. The figures are provided for purposes of illustration only and merely depict typical or example embodiments.

FIG. 1 illustrates an example of track segmenting in accordance with one embodiment.

FIG. 2 illustrates an example user interface in accordance with various embodiments.

FIG. 3 illustrates an example user interface when a driver changes trajectory, in accordance with various embodiments.

FIG. 4 illustrates an example method in accordance with one embodiment.

FIG. 5 is an example computing component that may be used to implement various features of embodiments described in the present disclosure.

The figures are not exhaustive and do not limit the present disclosure to the precise form disclosed.

### DETAILED DESCRIPTION

Racing teams can collect a large amount of data. This data can reflect parameters of a particular vehicle, such as vehicle state, speed, braking speed, or other parameters affecting the vehicle's performance. Vehicle data can be used to generate simulations of a driver's trajectory around a particular race track. These simulations can evaluate vehicle parameters and generate recommendations in the form of a recommended trajectory or list of suggested vehicle operating characteristics. Unfortunately, these simulations are generated before the driver operates the vehicle. If a driver deviates from the recommended trajectory, it may no longer be optimal to try to get back to and follow the recommended trajectory. For example, a driver may be advised to take an inner corner of a turn at a certain speed. If the driver increases his speed for any reason (i.e., to stay ahead of a challenger vehicle, to avoid an obstacle, etc.) then it may be unwise to continue trying to take the inner corner at the higher speed. Instead, the driver may need to take the outer corner while maintaining the increased speed.

Embodiments of the systems and methods disclosed herein can provide a machine learning model that recreates the action of an “expert driver”. In particular, drivers can test simulations of a race track while receiving input from the expert driver. The machine learning model can evaluate a driver's actions and compare them to the expert driver to provide a contemporaneous recommendation as the driver simulates traversing the race track. As the driver makes different decisions to follow or ignore the expert driver, the machine learning model can adapt and update recommendations to tailor the recommendations to the individual driver. These recommendations can take the form of a user interface that visually depicts a recommended trajectory as the driver traverses the simulated race track. Alternatively or additionally, the user interface can recommend vehicle settings to alter steering, braking, or other aspects of the vehicle's operation. For example, at a particular turn, the vehicle should be in a set gear, with the steering wheel angled at forty-five degrees. As the driver makes decisions and/or traverses the race track, the trajectory and/or suggested vehicle settings can visually update in real time to tailor recommendations based on the current situation.

The machine learning model can incorporate three different methodologies to generate these recommendations. First, reinforcement learning can be applied to train the model. The goal may be to minimize lap time by mapping a plurality of trajectories. Each trajectory may explore different variations of driver and vehicle states to determine the trajectory with a minimal lap time. For example, one trajectory may adjust speed to pass other vehicles on the straightaway, while another trajectory may adjust speed to pass other vehicles during a turn. Various decisions and states can be explored in mapping these trajectories. Decisions can include, but are limited to, aggression level (i.e., how a driver passes or follows other vehicles), driver preferences/experience level, acceleration as increased or decreased by the driver stepping on the gas or brake pedal, or any other decisions that may alter a vehicle's trajectory. Vehicle state information can include, but is not limited to, vehicle speed at different intervals/locations, vehicle acceleration, deceleration, tire position or turning radius, gas mileage, or any extrinsic or intrinsic characteristics of the vehicle that affect the vehicle's trajectory. Any or all of the decisions and vehicle states can be used to map various trajectories in order to select an optimal trajectory. Once the optimal trajectory is created, the system can provide an illustration of that trajectory and suggested vehicle settings to achieve that trajectory.

Second, trajectory data can be gathered from one or more expert drivers. The machine learning model can apply imitation learning with deep learning to train the model to predict actions. In particular, these actions can be predictions of how an expert driver would act in a given situation. For example, given expert driver data for a race track, the model can determine how an expert driver would accelerate out of a particular turn on the race track. As another example, the model can determine when an expert driver passes other vehicles. The machine learning model can apply different trajectories with the goal of matching or simulating the expert driver data. The model can test various vehicle states and driver decisions as described above in order to determine the actions that closely match the expert driver. The actions that closely match the expert driver can be recreated in the form of a suggested trajectory and/or an updating list of vehicle settings that allow a driver to recreate the expert driver's actions.

Third, a combination of reinforced learning and imitation learning can be applied to incorporate both methodologies described above. This can be accomplished by initially training the model with reinforced learning to minimize the lap time around a race track. The machine learning model can then be updated with regular human data to make its actions/decisions as realistic and human as possible. This configuration allows the machine learning model to focus on minimizing lap time while realistically incorporating an expert driver's limitations and strengths. The opposite can be applied as well, meaning that the machine learning model can initially be trained with expert driver data to match the expert driver. The trajectories that closely match the expert driver can then be used to train the model to minimize lap time. This combination would allow the machine learning model to determine which of the expert driver's actions are preferable to minimize lap time around the track. Alternatively, it is possible to alternate between reinforced learning and imitation learning. In this scenario, each iteration of training can be tied to either reinforced learning and/or imitation learning. For example, the system can be trained to minimize lap time around the track. Afterwards, the system can be trained to match the expert driver. When the model is updated with additional training, the system can return to minimizing the lap time.

Any combination of reinforced learning, imitation learning, and/or deep learning can be applied to train and regulate the machine learning model. The embodiments described herein are directed to the above methodologies, though other techniques can be applied to further enable the machine learning model to generate a recommended trajectory.

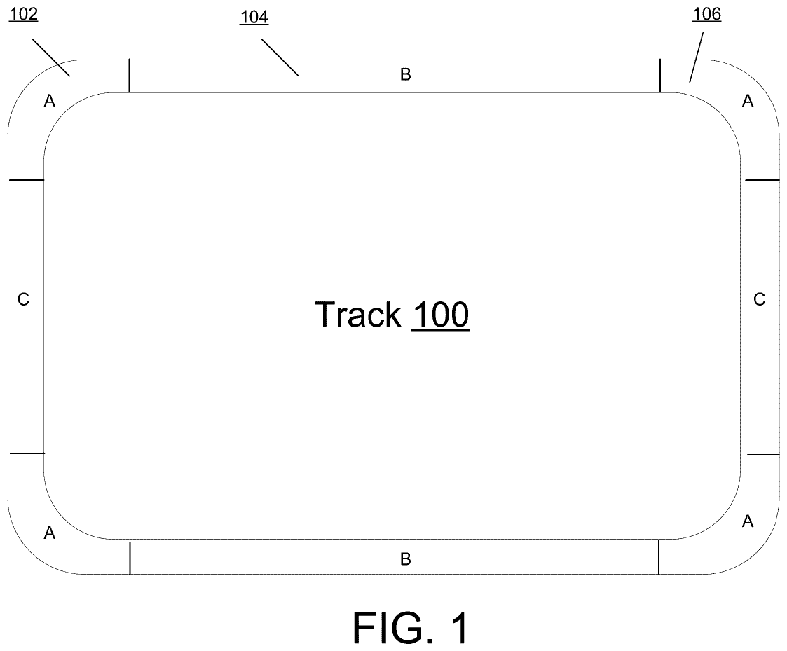

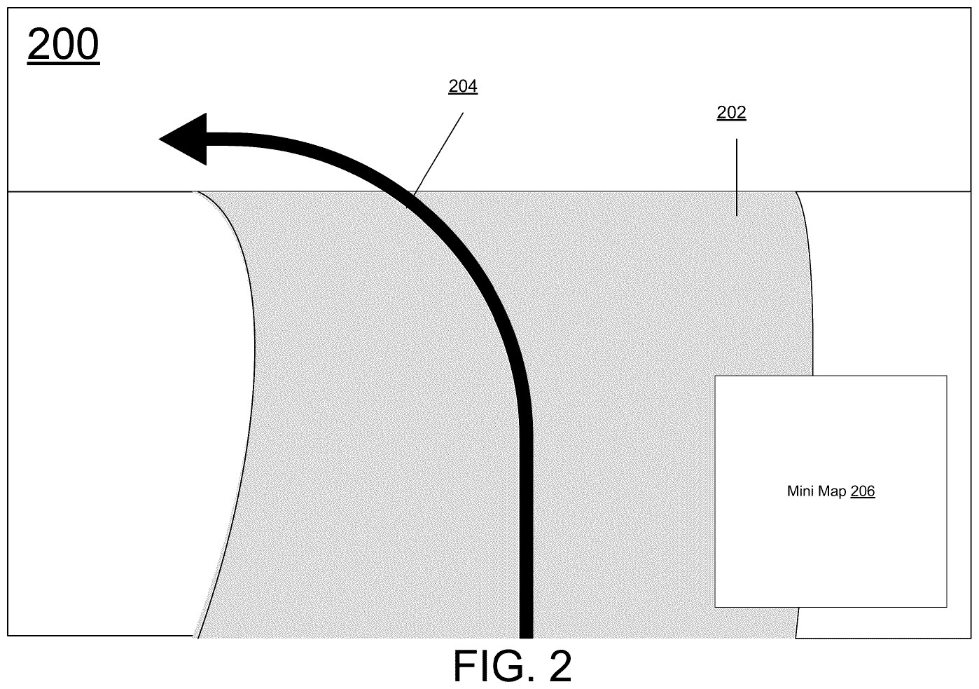

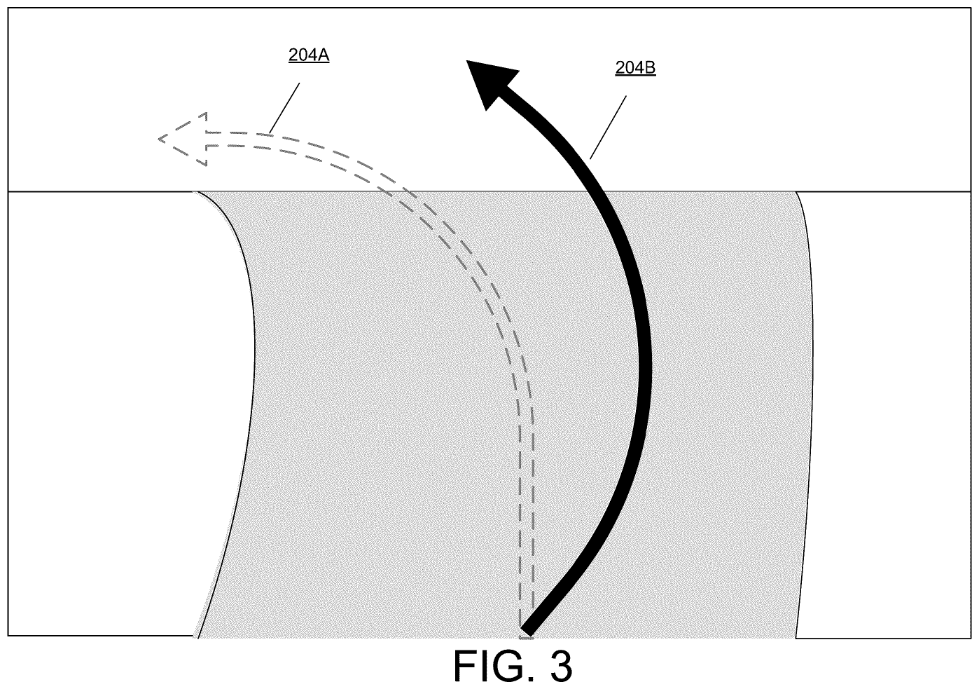

FIG. 1 illustrates an example race track 100 that can be visually displayed to a driver before or during a race simulation. Track 100 can take any shape based on the characteristics of the desired race track. The decisions and trajectory for track 100 can be extrapolated to other race tracks, such that recommendations can be translated to fit a different race track's varying curves and straightaways. Track 100 can be divided into segments, which can be color coded based on similarity. In the example of FIG. 1, track 100 is divided into eight segments and three groups based on similarity. Each group can be indicated by a corresponding letter. As described above, groups can be indicated by color coding, or any visual to show the separation to a user. The grouping and presentation of similar segments to the user can illustrate the similarities in strategy at various points of the track. Two similar segments can indicate that a similar or same strategy can be applied to optimize trajectory. Similar segments can also indicate a relative difficulty to assist a user in determining practice strategy. For instance, if two segments each share a relatively easy difficulty, it may be more advantageous for the user to focus on two other segments with a harder difficulty when practicing for a race. In some embodiments, an optimal driver model could be used in the segmentation process, as described below in FIGS. 2-3.

Segment 102 is an example of a turn around the race track. In the example of FIG. 1, track 100 is comprised of four ninety degree turns with curves of similar lengths. Accordingly, these four turns/corners can be identified as Group A. Group A can be identified based on various parameters, such as curvature, difficulty, or driver actions. Difficulty can be determined based on the number of iterations the machine learning model requires to determine an optimal trajectory or optimal vehicle settings. Alternatively, difficulty can be determined based on if the simulated driver can execute the recommended trajectory or vehicle settings. Difficulty can also be analyzed based on the driver's preferences in traversing the segment. For example, if a driver widely varies his trajectory during a segment, the machine learning model can indicate that the driver does not focus on the location along the width of the track. Accordingly, the segment may have an easier difficulty. Driver actions can define the start and end points of segments. For example, a driver suddenly decelerating can indicate the start of a turn. Likewise, a driver suddenly accelerating can indicate the end of a turn. Segments can be divided into further sub-segments based on these actions. For example, a turn may be divided into its deceleration phase, constant speed phase, and acceleration phase. These sub-segments can be further refined based on thresholds associated with the vehicle state. For example, the deceleration phase may comprise the segment where the driver is pressing the brake pedal one hundred percent. The second or middle segment can comprise the area where the driver has no force on the brakes. The last segment can comprise the area where the driver is pressing the throttle one hundred percent. The lessening of force on the throttle can signify the end of the last segment.

Segments can be grouped according to the type of track. Segment 104 comprises a straightaway along the longer side of the track. Segment 104 can be grouped into Group B to indicate straightaways along the length of the track. Similarly, segment 106 can comprise a straightaway along the shorter side of the track. Segment 106 can be grouped into Group C to indicate straightaways along the width of the track. This grouping can expand across multiple race tracks to show similarities between them. Grouping can be limited to tracks that are closed circuit tracks or open circuit tracks. This distinction can provide additional accuracy for similarities between the tracks because groups of closed circuit or open circuit tracks may have similar recommended trajectories and/or vehicle actions around or on a track. Grouping can also be limited to tracks following the same direction. Closed circuit tracks progressing in a clockwise direction can be similarly segmented, while closed circuit tracks progressing in a counterclockwise direction may have different segments.

FIG. 2 illustrates an example user interface 200 illustrating a recommended trajectory. User interface 200 can be incorporated into a simulation user interface while a driver simulates traversing a race track. User interface 200 may alternatively comprise a separate interface. In some embodiments, user interface 200 can comprise a first person view of the race track. User interface 200 may also provide a third person view of the track or a bird's eye view of a track. In the example of FIG. 2, user interface 200 can provide a first person view of the front of a track 202. The display of track 202 can simulate a driver's view through the front windshield as he traverses the race track.

User interface 200 can comprise an overlay of a recommended trajectory 204 that illustrates the location of the vehicle on the track. Recommended trajectory 204 may start in the center of the user interface to emulate the vehicle's current position. Alternatively, recommended trajectory 204 can be placed on the track to illustrate how far away the vehicle is from the trajectory. As illustrated in FIG. 2, recommended trajectory 204 can depict an upcoming turn or driver action and where to steer the vehicle appropriately. Recommended trajectory 204 can extend a distance in front of the first person view to illustrate the recommended trajectory. The length of recommended trajectory 204 can vary according to how recommended trajectory 204 updates. For example, if recommended trajectory 204 updates every fifty feet, recommended trajectory 204 may extend fifty feet in front of the first person view. If recommended trajectory 204 updates quickly, then recommended trajectory 204 may be even smaller. As described further below, user interface 200 can update in real time as the driver traverses the race track.

In some embodiments, user interface 200 can comprise a display of suggested vehicle settings and/or operating characteristics to achieve the recommended trajectory. For example, user interface 200 can indicate that the driver should be pressing the brake with fifty percent force while executing a turn. User interface 200 can also indicate the optimal speed at a particular point in the track and/or a suggested position of the steering wheel. User interface 200 can provide guidance as to the steering, braking, and/or speed of a vehicle at a particular point on the track. This guidance may be provided in addition to or alternatively to the recommended trajectory. As with recommended trajectory 204, the guidance can be updated at various intervals or positions along the track.

In some embodiments, user interface 200 can comprise a mini map 206. Mini map 206 may provide a bird's eye view of the whole race track. Mini map 206 may illustrate the simulation vehicle's position on the map. In some embodiments, mini map 206 can also illustrate a complete recommended trajectory around the entire race track. This trajectory can update as with recommended trajectory 204, or it may represent a recommended trajectory at the start of the race. Mini map 206 can thus indicate how far off a driver has strayed from recommendations. This disparity can assist in training the machine learning model to tailor to the driver's experience level or personal habits.

FIG. 3 illustrates how trajectory 204 can update as the driver makes varying decisions. Recommended trajectory 204A may be the starting recommendation for a particular segment based on the driver's current vehicle state and the expert driver data. At any point on the race track, the driver's current vehicle state can change. The vehicle state can comprise various parameters associated with the vehicle's operating characteristics. As mentioned above, vehicle state information can include, but is not limited to, vehicle speed at different intervals/locations, vehicle acceleration, deceleration, tire position or turning radius, gas mileage, or any extrinsic or intrinsic characteristics of the vehicle that affect the vehicle's trajectory.

FIG. 3 illustrates a time where the current vehicle state changes. For instance, the driver may suddenly accelerate, or the driver may begin a turn earlier or later than the recommended trajectory. Recommended trajectory 204 can update as illustrated with recommended trajectory 204B. As described above, the user interface can provide recommendations as to vehicle settings in addition to or alternatively to the recommended trajectory. If the vehicle state changes, for example, by an increase in speed, the user interface can indicate that the steering wheel should be at a different angle to optimally complete a turn. As another example, if the driver moves inward during a turn, the user interface can indicate that the driver should apply the brakes to safely traverse the shorter turn radius. As mentioned above, the goal may be to minimize lap time. The system can map different trajectories that incorporate the driver's current decisions, in order to determine a minimal lap time. The system can predict future decisions based on the data accumulated as the driver traverses the race track. For example, based on a driver's experience or difficulty with a segment, the system can determine that the driver will take the upcoming turn at a specific turning radius. The system can update the recommended trajectory and vehicle settings to lead the driver to the start of the turn in the shortest amount of time. The machine learning model may also predict how an expert driver would react in the situation. As described above, the machine learning model can apply different trajectories with the goal of matching or simulating the expert driver data. The model can test variations of vehicle states and driver decisions corresponding to the current vehicle state in order to determine the actions that closely match the expert driver. A combination of reinforced learning and imitation learning can also be applied. The machine learning model can then be updated with the driver data to make its actions/decisions as realistic and human as possible. Alternatively, the machine learning model can be updated using expert driver trajectories to overlay an expert driver trajectory based on the current vehicle state.

Recommended trajectory 204 can update at various time intervals. Recommended trajectory 204 can update in real-time as the driver traverses the race track. In some embodiments, recommended trajectory 204 can update in time intervals to make it easier for a driver to visualize. Recommended trajectory 204 can also update in distance intervals or segment intervals. For example, recommended trajectory 204 may focus on a current turn around the race track. At the end of the turn, recommended trajectory 204 can update to reflect the upcoming straightaway. Recommended trajectory 204 can change intervals based on driver input or automatic changes. Recommended vehicle settings can be similarly updated as the driver traverses the track. The user interface may provide a dynamic window that changes vehicle settings at set intervals or after certain driver actions. For example, the suggested settings may change when the vehicle accelerates or begins to turn. Alternatively, the suggested settings may change at the start of each segment of the race track. The recommended vehicle settings can be updated similar to the recommended trajectory or may update independently based on different parameters/intervals.

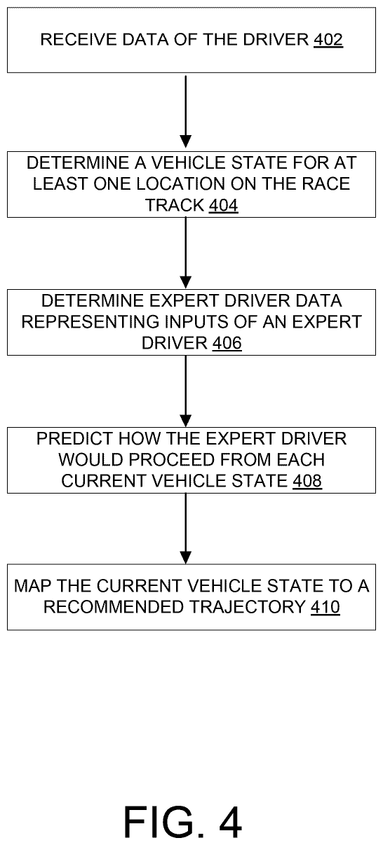

FIG. 4 illustrates an example method in accordance with the embodiments described herein. At block 402, the system can receive data of the driver. As described above, the system can receive data in real time as the driver traverses around a simulated or actual race track. The system can also incorporate past simulation or racing data to further tailor the recommended trajectories. This data can be used to further train and update the machine learning model. As the driver completes additional tracks, the system can determine the driver's experiences and predict the driver's actions. These predictions can be used to tailor the recommended trajectory and/or vehicle settings.

At block 404, the system can determine a vehicle state for each of one or more locations on the race track based on the simulation data. As describe above, the system can analyze the vehicle state in real time as the driver progresses during the simulation. Using the real-time data, the system can determine the vehicle state at the present moment. The vehicle state can include vehicle speed at different intervals/locations, vehicle acceleration, deceleration, tire position or turning radius, gas mileage, or any extrinsic or intrinsic characteristics of the vehicle that affect the vehicle's trajectory. The vehicle state at future locations can be predicted using past simulation data. For example, if a driver consistently accelerates a certain distance before a turn, the system can predict the vehicle state at an upcoming turn.

At block 406, the system can determine expert driver data representing inputs of an expert driver. As described above, expert driver data can comprise racing or simulation data of one or more expert drivers. Expert driver data can reflect the specific simulated race track. Alternatively, expert driver decisions can be determined from data of similar tracks. The system can predict how the expert driver would react at the present race track given the similarities between the two tracks.

At block 408, the system can predict how the expert driver would proceed from each current vehicle state based on the expert driver data. For example, the system may determine the steering, throttle and brake inputs that an expert driver might make in the same situation. The machine learning model can test different trajectories with the goal of matching or simulating the expert driver data. The machine learning model can be trained based on expert driver data representing expert driver inputs the expert may make to achieve trajectories that may also minimize the lap time. The system can compare trajectories of the whole race track or particular segments. The model can test various vehicle states and driver decisions as described above in order to determine the actions that closely match the expert driver.

This model can be developed in various ways. For example, reinforcement learning may be used to train a driver model to minimize the lap time around the track from exploring many different trajectories in the simulator. As another example, the system can collect trajectory data from expert human drivers and use imitation learning with deep learning to train a model to predict the action that an expert human driver would most likely take. Embodiments may also use a combination of both of the above, such as initially training a model with reinforced learning and then regularizing it with human data to ensure that its actions are realistic relative to what a human driver would do.

At block 410, the system can map a recommended trajectory from each current vehicle state based on determining how the expert driver would proceed (i.e., based on expert driver inputs). As illustrated above in FIGS. 2 and 3, the recommended trajectory can be mapped using a user interface. The user interface can comprise a first person view of the race track. The user interface can comprise an overlay of the recommended trajectory and illustrate the location of the vehicle on the track. The recommended trajectory can depict an upcoming turn or driver action and where to steer the vehicle appropriately. The length of the recommended trajectory can vary according to how the recommended trajectory updates.

Alternatively or additionally, the system can map recommended vehicle settings based on determining how the expert driver would proceed. As mentioned above, the user interface can provide a list of vehicle settings as to a vehicle's braking, steering, or throttling at the current vehicle state. The user interface can list these settings in a dynamic window or may integrate the settings into the first person view of the racing track. As the driver traverses the race track and makes different decisions, recommended vehicle settings can be updated at various intervals as with the recommended trajectory.

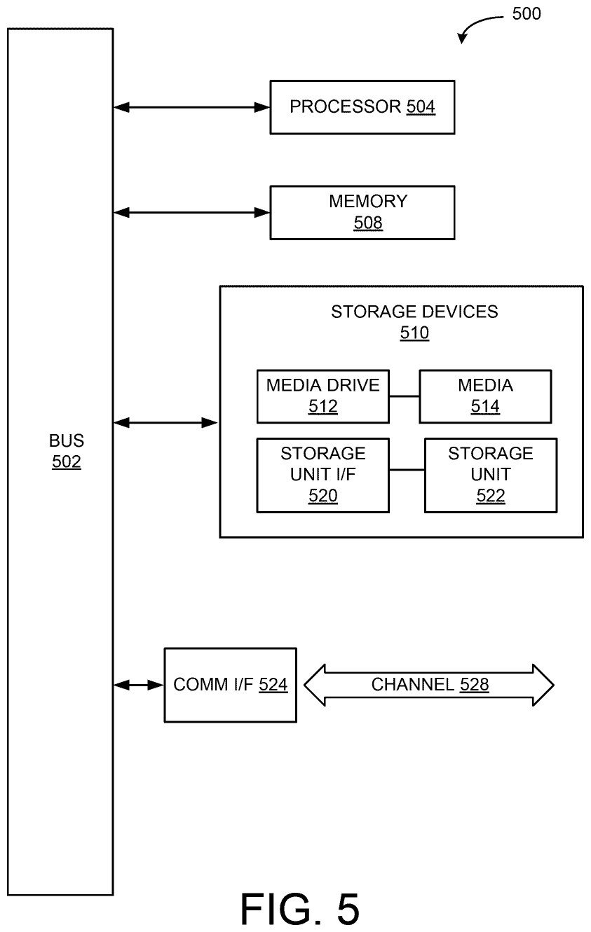

As used herein, the terms circuit and component might describe a given unit of functionality that can be performed in accordance with one or more embodiments of the present application. As used herein, a component might be implemented utilizing any form of hardware, software, or a combination thereof. For example, one or more processors, controllers, ASICs, PLAS, PALs, CPLDs, FPGAs, logical components, software routines or other mechanisms might be implemented to make up a component. Various components described herein may be implemented as discrete components or described functions and features can be shared in part or in total among one or more components. In other words, as would be apparent to one of ordinary skill in the art after reading this description, the various features and functionality described herein may be implemented in any given application. They can be implemented in one or more separate or shared components in various combinations and permutations. Although various features or functional elements may be individually described or claimed as separate components, it should be understood that these features/functionality can be shared among one or more common software and hardware elements. Such a description shall not require or imply that separate hardware or software components are used to implement such features or functionality.

Where components are implemented in whole or in part using software, these software elements can be implemented to operate with a computing or processing component capable of carrying out the functionality described with respect thereto. One such example computing component is shown in FIG. 5. Various embodiments are described in terms of this example-computing component 500. After reading this description, it will become apparent to a person skilled in the relevant art how to implement the application using other computing components or architectures.

Referring now to FIG. 5, computing component 500 may represent, for example, computing or processing capabilities found within a self-adjusting display, desktop, laptop, notebook, and tablet computers. They may be found in hand-held computing devices (tablets, PDA's, smart phones, cell phones, palmtops, etc.). They may be found in workstations or other devices with displays, servers, or any other type of special-purpose or general-purpose computing devices as may be desirable or appropriate for a given application or environment. Computing component 500 might also represent computing capabilities embedded within or otherwise available to a given device. For example, a computing component might be found in other electronic devices such as, for example, portable computing devices, and other electronic devices that might include some form of processing capability.

Computing component 500 might include, for example, one or more processors, controllers, control components, or other processing devices. Processor 504 might be implemented using a general-purpose or special-purpose processing engine such as, for example, a microprocessor, controller, or other control logic. Processor 504 may be connected to a bus 502. However, any communication medium can be used to facilitate interaction with other components of computing component 500 or to communicate externally.

Computing component 500 might also include one or more memory components, simply referred to herein as main memory 508. For example, random access memory (RAM) or other dynamic memory, might be used for storing information and instructions to be executed by processor 504. Main memory 508 might also be used for storing temporary variables or other intermediate information during execution of instructions to be executed by processor 504. Computing component 500 might likewise include a read only memory (“ROM”) or other static storage device coupled to bus 502 for storing static information and instructions for processor 504.

The computing component 500 might also include one or more various forms of information storage mechanism 510, which might include, for example, a media drive 512 and a storage unit interface 520. The media drive 512 might include a drive or other mechanism to support fixed or removable storage media 514. For example, a hard disk drive, a solid-state drive, a magnetic tape drive, an optical drive, a compact disc (CD) or digital video disc (DVD) drive (R or RW), or other removable or fixed media drive might be provided. Storage media 514 might include, for example, a hard disk, an integrated circuit assembly, magnetic tape, cartridge, optical disk, a CD or DVD. Storage media 514 may be any other fixed or removable medium that is read by, written to or accessed by media drive 512. As these examples illustrate, the storage media 514 can include a computer usable storage medium having stored therein computer software or data.

In alternative embodiments, information storage mechanism 510 might include other similar instrumentalities for allowing computer programs or other instructions or data to be loaded into computing component 500. Such instrumentalities might include, for example, a fixed or removable storage unit 522 and an interface 520. Examples of such storage units 522 and interfaces 520 can include a program cartridge and cartridge interface, a removable memory (for example, a flash memory or other removable memory component) and memory slot. Other examples may include a PCMCIA slot and card, and other fixed or removable storage units 522 and interfaces 520 that allow software and data to be transferred from storage unit 522 to computing component 500.

Computing component 500 might also include a communications interface 524. Communications interface 524 might be used to allow software and data to be transferred between computing component 500 and external devices. Examples of communications interface 524 might include a modem or softmodem, a network interface (such as Ethernet, network interface card, IEEE 802.XX or other interface). Other examples include a communications port (such as for example, a USB port, IR port, RS232 port Bluetooth® interface, or other port), or other communications interface. Software/data transferred via communications interface 524 may be carried on signals, which can be electronic, electromagnetic (which includes optical) or other signals capable of being exchanged by a given communications interface 524. These signals might be provided to communications interface 524 via a channel 528. Channel 528 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to transitory or non-transitory media. Such media may be, e.g., memory 508, storage unit 522, media 514, and channel 528. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing component 500 to perform features or functions of the present application as discussed herein.

It should be understood that the various features, aspects and functionality described in one or more of the individual embodiments are not limited in their applicability to the particular embodiment with which they are described. Instead, they can be applied, alone or in various combinations, to one or more other embodiments, whether or not such embodiments are described and whether or not such features are presented as being a part of a described embodiment. Thus, the breadth and scope of the present application should not be limited by any of the above-described exemplary embodiments.

Terms and phrases used in this document, and variations thereof, unless otherwise expressly stated, should be construed as open ended as opposed to limiting. As examples of the foregoing, the term “including” should be read as meaning “including, without limitation” or the like. The term “example” is used to provide exemplary instances of the item in discussion, not an exhaustive or limiting list thereof. The terms “a” or “an” should be read as meaning “at least one,” “one or more” or the like; and adjectives such as “conventional,” “traditional,” “normal,” “standard,” “known.” Terms of similar meaning should not be construed as limiting the item described to a given time period or to an item available as of a given time. Instead, they should be read to encompass conventional, traditional, normal, or standard technologies that may be available or known now or at any time in the future. Where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “component” does not imply that the aspects or functionality described or claimed as part of the component are all configured in a common package. Indeed, any or all of the various aspects of a component, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A method for optimizing a driver's trajectory around a race track, comprising:
receiving driver data representing driver inputs to a vehicle;
determining a vehicle state for at least one location on the race track based on the received driver data;
determining expert driver data representing inputs of an expert driver at the determined vehicle state for the at least one location;
predicting how the expert driver would proceed from each current vehicle state based on the expert driver data; and
mapping the current vehicle state at the at least one location to a recommended trajectory from each current vehicle state based on predicting how the expert driver would proceed.

2. The method of claim 1, further comprising displaying the recommended trajectory on a user interface as the driver simulates driving around the race track.

3. The method of claim 2, further comprising updating the displayed recommended trajectory when the driver changes vehicle state.

4. The method of claim 3, wherein updating the displayed recommended trajectory comprises determining how the expert driver would proceed from the changed vehicle state and mapping a new recommended trajectory.

5. The method of claim 1, further comprising segmenting the race track and categorizing each segment of the race track.

6. The method of claim 5, further comprising categorizing the driver data based on a corresponding segment.

7. The method of claim 1, wherein determining how the expert driver would proceed from each current vehicle state is based on minimizing a lap time around the race track.

8. The method of claim 1, further comprising training a machine learning model with reinforced learning and regulating the machine learning model with additional simulation data to match human actions.

9. A system for simulating driving around a race track, comprising:
a processor; and
a memory coupled to the processor to store instructions, which when executed by the processor, cause the processor to:
receive driver data representing driver inputs to a vehicle;
determine a current vehicle state for at least one location on the race track based on the received driver data;
determine expert driver data representing inputs of an expert driver at the determined vehicle state for the at least one location;
predict how the expert driver would proceed from each current vehicle state based on the expert driver data; and
map the current vehicle state at the at least one location to one or more recommended vehicle settings for a remaining portion of the race track based on predicting how the expert driver would proceed.

10. The system of claim 9, wherein the instructions further cause the processor to display the one or more recommended vehicle settings on a user interface as the driver simulates driving around the race track.

11. The system of claim 9, wherein the instructions further cause the processor to segment the race track and categorize each segment of the race track.

12. The system of claim 11, wherein determining how the expert driver would proceed is based on a corresponding category of segment of the race track.

13. The system of claim 9, wherein determining how the expert driver would proceed from each current vehicle state is based on minimizing a lap time around the race track.

14. The system of claim 9, wherein the instructions further cause the processor to train a machine learning model with reinforced learning and regulate the machine learning model with additional simulation data to match human actions.

15. A non-transitory machine-readable medium having instructions stored therein, which when executed by a processor, cause the processor to:
receive driver data representing driver inputs to a vehicle;
determine a current vehicle state for at least one location on a race track based on the received driver data;
determine expert driver data representing inputs of an expert driver at the determined vehicle state for the at least one location;
predict how the expert driver would proceed from each current vehicle state based on the expert driver data;
map the current vehicle state at the at least one location to a recommended trajectory from each current vehicle state based on predicting how the expert driver would proceed; and
display the recommended trajectory on a user interface as the driver traverses the race track.

16. The non-transitory machine-readable medium of claim 15, wherein the instructions further cause the processor to update the displayed recommended trajectory when the driver changes vehicle state.

17. The non-transitory machine-readable medium of claim 16, wherein the instructions further cause the processor to determine how the expert driver would proceed from the changed vehicle state and mapping a new recommended trajectory.

18. The non-transitory machine-readable medium of claim 15, wherein the instructions further cause the processor to segment the race track and categorize each segment of the race track.

19. The non-transitory machine-readable medium of claim 15, wherein the instructions further cause the processor to categorize the data based on a corresponding segment.

20. The non-transitory machine-readable medium of claim 15, wherein determining how the expert driver would proceed from each current vehicle state is based on minimizing a lap time around the race track.
